(19) United States
(12) Patent Application Publication
(10) Pub. No.: US 2014/0231951 A1
(43) Pub. Date: Aug. 21, 2014

(54) SILICON PHOTOMULTIPLIER AND METHOD OF MANUFACTURING SILICON PHOTOMULTIPLIER

(71) Applicant: Electronics and Telecommunications Research Institute, Daejeon (KR)

(72) Inventors: Yong Sun YOON, Daejeon (KR); Ji Eun LIM, Daejeon (KR); Han Young YU, Daejeon (KR); Won Ick JANG, Daejeon (KR)

(73) Assignee: Electronics and Telecommunications Research Institute, Daejeon (KR)

(21) Appl. No.: 14/181,053

(22) Filed: Feb. 14, 2014

(30) Foreign Application Priority Data
Feb. 15, 2013 (KR) 10-2013-0016481

(51) Int. Cl. H01L 27/144; H01L 31/028; H01L 31/18

(52) U.S. Cl. CPC H01L 27/144; H01L 31/1804; H01L 31/028
USPC 257/461; 438/59

(57) ABSTRACT

Provided is a structure of a silicon photomultiplier including an insulating layer to isolate pixels in the silicon photomultiplier and a quench resistor formed on the insulating layer to maximize the size of a light-receiving area, and a method of manufacturing the silicon photomultiplier.

### CROSS-REFERENCE TO RELATED APPLICATION

This application claims the priority benefit of Korean Patent Application No. 10-2013-0016481, filed on Feb. 15, 2013, in the Korean Intellectual Property Office, the disclosure of which is incorporated herein by reference.

### BACKGROUND

1. Field of the Invention

The present invention relates to a structure of a multi-pixel silicon photomultiplier and a method of manufacturing the silicon photomultiplier to enhance a fill factor.

2. Description of the Related Art

A silicon photomultiplier (SiPM) is a device that may extract a single photon, and is receiving attention as a replacement of a photomultiplier tube due to a small size, a low operating voltage, and a reduced effect from a magnetic field, when compared to an existing photomultiplier (PMT).

A task performed by the silicon photomultiplier, for example, Photon detection efficiency (PDE), may depend on quantum efficiency based on a wavelength, an avalanche trigger probability, and a fill factor. Here, a fill factor is defined as an area ratio of a light-receiving area to a dead area.

The quantum efficiency and the avalanche trigger probability may depend on a wavelength of an incident light, a surface coating and doping structure, and an applied voltage. The fill factor may be determined by the structure (*of the silicon photomultiplier?.

When a number of pixels in one silicon photomultiplier increases, the fill factor may decrease to 50% or lower. In a case of configuring the silicon photomultiplier as a high-density device, a size of a quench resistor does not decrease and a size of the light-receiving area in each pixel decreases. Accordingly, a significant increase may occur in the fill factor.

FIG. 1 illustrates a multi-pixel silicon photomultiplier according to a related art.

Referring to FIG. 1, the multi-pixel silicon photomultiplier may include a light-receiving area 110, a quench resistor 120, a metal electrode 130, an electrode contact portion 140, and an insulating layer 150 to isolate pixels.

In the silicon photomultiplier, the quench resistor 120 is formed on the light-receiving area 110 and thus, a fill factor may be reduced when the light-receiving area 110 is decreased by an amount corresponding to an area of the quench resistor 120. Such a phenomenon may lead to further deterioration in the case of a silicon photomultiplier in which a number of pixels within the silicon photomultiplier increases and accordingly is highly integrated. Thus, improving the structure of the silicon photomultiplier is necessary to enhance the fill factor.

### SUMMARY

According to an aspect of the present invention, there is provided a silicon photomultiplier including an insulating layer to isolate pixels in the silicon photomultiplier and a quench resistor formed on the insulating layer to maximize a size of a light-receiving area.

The silicon photomultiplier may further include a metal electrode to connect an upper pad of the silicon photomultiplier to the quench resistor.

The metal electrode may connect the quench resistor to an upper doping layer of the light-receiving area.

The silicon photomultiplier may further include an electrode contact portion to electrically connect the metal electrode, the light-receiving area, and the quench resistor through the insulating layer.

The silicon photomultiplier may further include a substrate and an interlayer formed between the substrate and the insulating layer.

The silicon photomultiplier may further include a junction doping layer formed on the interlayer and an upper doping layer formed on the junction doping layer.

The substrate and the interlayer may be formed using an epitaxy process.

The upper doping layer and the junction doping layer may be formed using an ion implantation process.

The silicon photomultiplier may further include a guide ring formed between the interlayer and the insulating layer to prevent an occurrence of a premature breakdown at an edge of the upper doping layer.

The substrate, the interlayer, the junction doping layer, and the upper doping layer may be distinguished from one another based on a doping type and a concentration of silicon, and may be formed in a vertical diode structure.

According to another aspect of the present invention, there is provided a method of manufacturing the silicon photomultiplier, including forming the insulating layer to isolate pixels in the silicon photomultiplier and forming the quench resistor on the insulating layer to maximize the size of the light-receiving area.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 illustrates a multi-pixel silicon photomultiplier according to a related art;

FIG. 2 is a plan view of a structure of a silicon photomultiplier according to an embodiment of the present invention;

FIG. 3 is a cross-sectional view of a unit pixel of a silicon photomultiplier cut along line “A” of FIG. 2 according to an embodiment of the present invention; and

FIG. 4 is a flowchart illustrating a method of manufacturing a silicon photomultiplier according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the accompanying drawings, however, the present invention is not limited thereto or restricted thereby.

When it is determined detailed description related to a related known function or configuration they may make the purpose of the present invention unnecessarily ambiguous in describing the present invention, the detailed description will be omitted here. Also, terminology used herein is defined to appropriately describe the exemplary embodiments of the present invention and thus may be changed depending on a user, the intent of an operator, or a custom. Accordingly, the terms must be defined based on the following overall description of this specification.

According to an embodiment of the present invention, a silicon photomultiplier may have a structure in which a fill factor is improved by disposing a quench resistor on a dead area on which an insulating layer to isolate multiple pixels in the silicon photomultiplier is formed and thus, a light-receiving area may be maximized.

The silicon photomultiplier has a diode structure in which a doping layer is disposed on a light-receiving surface to be parallel therewith, and may operate at a voltage higher than a breakdown voltage.

In the silicon photomultiplier, a signal may be amplified as a number of carriers increases exponentially due to impact ionization as an electron-hole pair generated when light, for example, a photon, enters the light-receiving area and the generation is accelerated by an internal magnetic field.

A detector applying the method above may detect a number of photons entering the silicon photomultiplier by configuring the silicon photomultiplier using multiple pixels connected in parallel and measuring an amount of current generated concurrently from the silicon photomultiplier.

For example, since the dynamic range with respect to light intensity of the silicon photomultiplier may depend on an area of a unit pixel and a number of unit pixels with respect to an entire area of the silicon photomultiplier, forming a high-density pixel pattern to improve the dynamic range may be effective.

When a breakdown occurs in a single pixel, the pixel may not be operable during such a period. A passive quenching method of connecting a quench resistor in series to the diode structure of the pixel may be applied to prevent damage to the silicon photomultiplier caused by an overcurrent.

The quench resistor may discharge a voltage applied to the silicon photomultiplier to a voltage lower than a breakdown voltage by inducing a voltage drop when an overcurrent flows due to the electrical breakdown.

Hereinafter, the structure of the silicon photomultiplier will be described in detail according to an embodiment of the present invention.

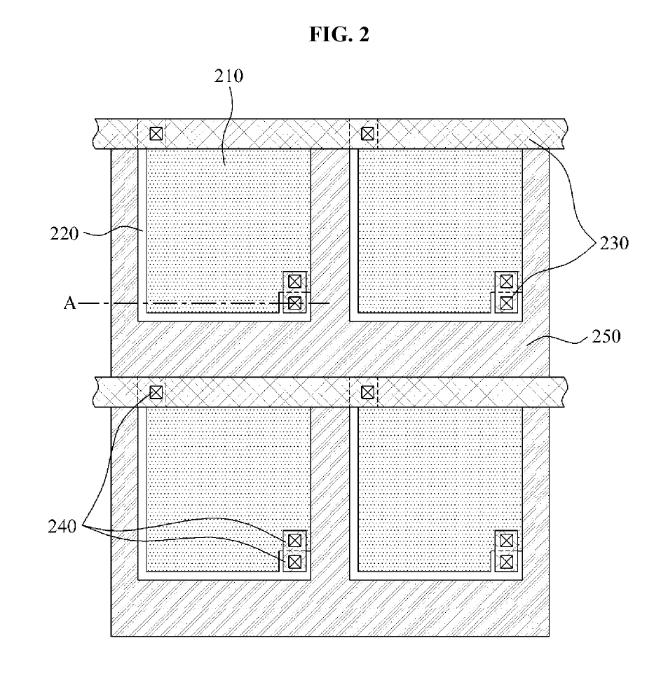

FIG. 2 is a plan view illustrating a structure of a silicon photomultiplier according to an embodiment of the present invention.

Referring to FIG. 2, the silicon photomultiplier may have a structure in which a plurality of pixels is connected in parallel, and include an insulating layer 250 to isolate pixels in the silicon photomultiplier and a quench resistor 220 formed on the insulating layer 250 to maximize a size of a light-receiving area 210.

The silicon photomultiplier may form a metal electrode 230 to connect an upper pad of the silicon photomultiplier to the quench resistor 220. The metal electrode 230 may connect the quench resistor 220 to an upper doping layer of the light-receiving area 210.

The silicon photomultiplier may form an electrode contact portion 240 to electrically connect the metal electrode 230, the light-receiving area 210, and the quench resistor 220 through the insulating layer 250.

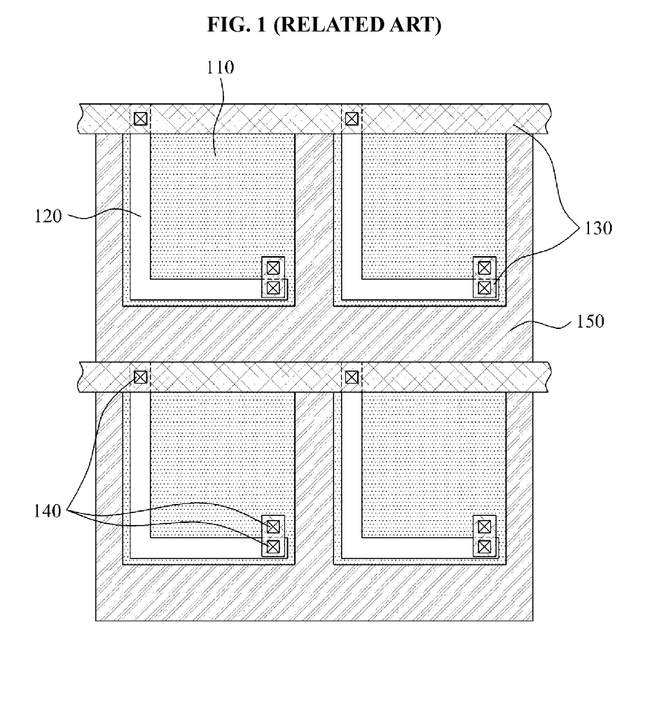

The light-receiving area 210 in which light enters may be configured in a planar diode structure. In the light-receiving area 210, an electrical breakdown may occur due to impact ionization as an electron-hole pair is generated when a photon enters and the generation is accelerated by an internal electromagnetic field. As shown in FIG. 1, a fill factor may be reduced when the light-receiving area 110 is decreased by an amount corresponding to an area of the quench resistor and the quench resistor 120 is formed on the light-receiving area 110, which may worsen in the case of a silicon photomultiplier in which a number of pixels within the silicon photomultiplier increases and accordingly is highly integrated. As shown in FIG. 2, a reduction of the fill factor may be improved by changing the area on which the quench resistor 220 is formed.

The quench resistor 220 connected in series to the light-receiving area 210 may discharge a voltage applied to the silicon photomultiplier to a voltage lower than a breakdown voltage by inducing voltage drop when an overcurrent flows due to an electrical breakdown, and may be configured in the form of a semiconductor using polysilicon and the like. Also, the size of the light-receiving area 210 may be maximized by forming the quench resistor 220 on the insulating layer 250 to isolate pixels in the silicon photomultiplier, instead of forming the quench resistor 220 on the light-receiving area 210.

The metal electrode 230 may connect the upper pad of the silicon photomultiplier to the quench resistor 220, and connect the quench resistor 220 of each pixel to the upper doping layer of the light-receiving area 210.

The electrode contact portion 240 may electrically connect the metal electrode 230, the light-receiving area 210, and the quench resistor 220 through the insulating layer 250 to isolate pixels.

According to an embodiment of the present invention, the light-receiving area 210 in which light enters may be configured in a planar diode structure. In the light-receiving area 210, an electrical breakdown may occur due to impact ionization as an electron-hole pair is generated when a photon enters and the generation is accelerated by an internal electromagnetic field.

When the quench resistor 120 is formed on the light-receiving area 110 as shown in FIG. 1, the fill factor may be reduced when the light-receiving area 110 is decreased by an amount corresponding to an area of the quench resistor, which may worsen in a case of a silicon photomultiplier in which a number of pixels within the silicon photomultiplier increases and accordingly is highly integrated.

According to an embodiment of the present invention, the silicon photomultiplier may improve a fill factor by changing the area on which the quench resistor 220 is formed, as shown in FIG. 2.

The quench resistor 220 connected in series to the light-receiving area 210 may discharge a voltage applied to the silicon photomultiplier to a voltage lower than a breakdown voltage by inducing a voltage drop when an overcurrent flows due to the electrical breakdown. The quench resistor 220 may be formed as a semiconductor using polysilicon and the like.

Further, the size of the light-receiving area 210 may be maximized by forming the quench resistor 220 on the insulating layer 250 to isolate pixels in the silicon photomultiplier, instead of forming the quench resistor 220 on the light-receiving area 210.

The metal electrode 230 may connect the upper pad of the silicon photomultiplier to the quench resistor 220, and connect the quench resistor 220 of each pixel to the upper doping layer of the light-receiving area 210.

The electrode contact portion 240 may electrically connect the metal electrode 230, the light-receiving area 210, and the quench resistor 220 through the insulating layer 250 for isolating pixels.

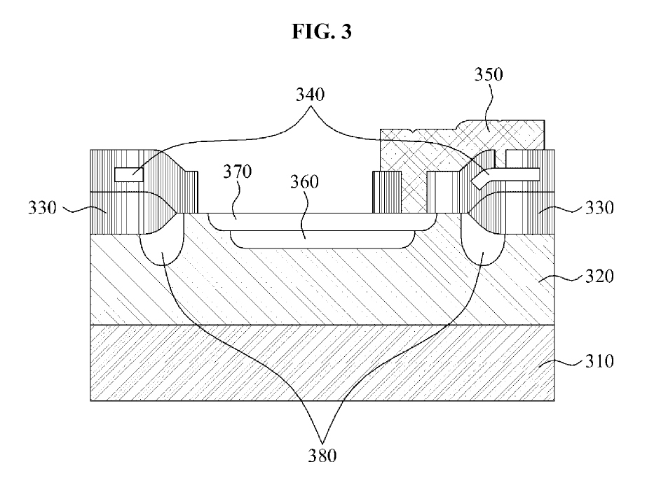

FIG. 3 is a cross-sectional view of a unit pixel of a silicon photomultiplier cut along line “A” of FIG. 2 according to an embodiment of the present invention.

According to an embodiment of the present invention, the silicon photomultiplier may include a substrate 310 and an interlayer 320 formed between the substrate 310 and an insulating layer 330. Also, the silicon photomultiplier may include a junction doping layer 360 formed on the interlayer 320, and an upper doping layer 370 formed on the junction doping layer 360.

The silicon photomultiplier may have a structure in which a plurality of pixels is connected in parallel, and include the insulating layer 330 to isolate pixels in the silicon photomultiplier and a quench resistor 340 formed on the insulating layer 330 to maximize a size of a light-receiving area.

The metal electrode 350 may connect the upper pad of the silicon photomultiplier to the quench resistor 340 and connect the quench resistor 340 of each pixel to the upper doping layer 370 of the light-receiving area.

According to an embodiment of the present invention, the substrate 310 and the interlayer 320 may be formed using an epitaxy process, and the upper doping layer 370 and the junction doping layer 360 may be formed using an ion implantation process.

The silicon photomultiplier may include a guide ring 380 formed between the interlayer 320 and the insulating layer 330. The guide ring 380 may prevent an occurrence of a premature breakdown at an edge of the upper doping layer 370. The premature breakdown refers to a phenomenon occurring at a voltage lower than a predetermined breakdown voltage.

According to an embodiment of the present invention, the substrate 310, the junction doping layer 360, and the upper doping layer 370 may be distinguished from one another based on a doping type and a concentration of silicon, and formed in a vertical diode structure.

For example, the upper doping layer 370, the junction doping layer 360, the interlayer 320, and the substrate 310 may be p+/n/n−/n+ doping layer or n+/p/p−/p+ doping layer, respectively.

The insulating layer 330 is an insulator to isolate pixels that may be made of silicon dioxide or silicon nitride, and the like. The upper portion of the insulating layer 330 area may be used to form the quench resistor 340.

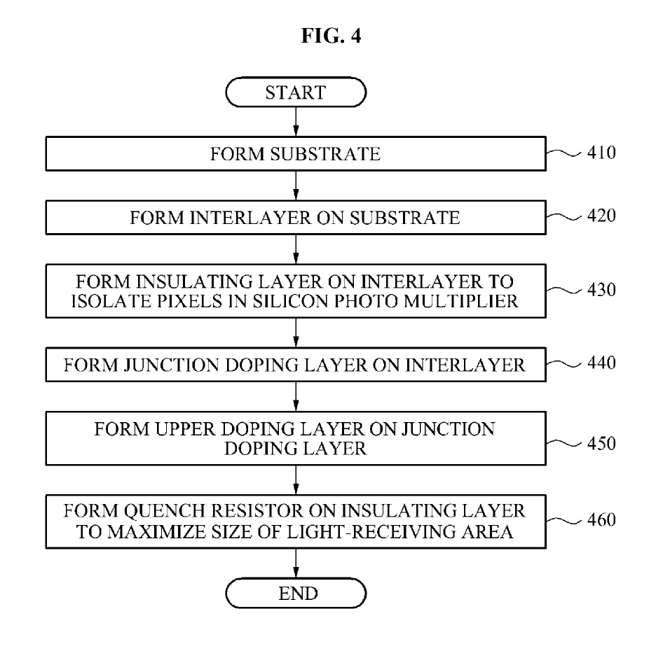

Hereinafter, a method of manufacturing a silicon photomultiplier according to an embodiment of the present invention will be described in detail with reference to FIG. 4.

FIG. 4 is a flowchart illustrating a method of manufacturing a silicon photomultiplier according to an embodiment of the present invention.

Referring to FIG. 4, the method of manufacturing the silicon photomultiplier may form a substrate in operation 410, form an interlayer on the substrate in operation 420, and form an insulating layer on the interlayer to isolate pixels in the silicon photomultiplier in operation 430.

The method of manufacturing the silicon photomultiplier may form a junction doping layer on the interlayer in operation 440, and form an upper doping layer on the junction doping layer in operation 450.

The method of manufacturing the silicon photomultiplier may form a quench resistor on the insulating layer to maximize a size of a light-receiving area in operation 460.

Disclosed herein are exemplary embodiments of the method of manufacturing the silicon photomultiplier, and thus, forming any of the layers first may be possible when structures of gaps between individual layers are identical.

According to an embodiment of the present invention, there may be provided a structure of a silicon multiplier to enhance a fill factor.

According to an embodiment of the present invention, there may be provided a structure of a silicon multiplier in which a fill factor is improved by disposing a quench resistor on a dead area on which an insulating layer to isolate multi-pixels in the silicon photomultiplier is formed an thus, a light-receiving area may be maximized.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A silicon photomultiplier, comprising:
an insulating layer to isolate pixels in the silicon photomultiplier; and
a quench resistor formed on the insulating layer to maximize a size of a light-receiving area.

2. The silicon photomultiplier of claim 1, further comprising:
a metal electrode to connect an upper pad of the silicon photomultiplier to the quench resistor.

3. The silicon photomultiplier of claim 2, wherein the metal electrode connects the quench resistor to an upper doping layer of the light-receiving area.

4. The silicon photomultiplier of claim 2, further comprising:
an electrode contact portion to electrically connect the metal electrode, the light-receiving area, and the quench resistor through the insulating layer.

5. The silicon photomultiplier of claim 1, further comprising:
a substrate; and
an interlayer formed between the substrate and the insulating layer.

6. The silicon photomultiplier of claim 5, further comprising:
a junction doping layer formed on the interlayer; and
an upper doping layer formed on the junction doping layer.

7. The silicon photomultiplier of claim 5, wherein the substrate and the interlayer are formed using an epitaxy process.

8. The silicon photomultiplier of claim 6, wherein the upper doping layer and the junction doping layer are formed using an ion implantation process.

9. The silicon photomultiplier of claim 6, further comprising:
a guide ring formed between the interlayer and the insulating layer to prevent an occurrence of a premature breakdown at an edge of the upper doping layer.

10. The silicon photomultiplier of claim 6, wherein the substrate, the interlayer, the junction doping layer, and the upper doping layer are distinguished from one another based on a doping type and a concentration of silicon, and formed in a vertical diode structure.

11. A method of manufacturing a silicon photomultiplier, the method comprising:
forming an insulating layer to isolate pixels in the silicon photomultiplier; and
forming a quench resistor on the insulating layer to maximize a size of a light-receiving area.

12. The method of claim 11, further comprising:
forming a metal electrode to connect an upper pad of the silicon photomultiplier to the quench resistor.

13. The method of claim 12, wherein the metal electrode connects the quench resistor to an upper doping layer of the light-receiving area.

14. The method of claim 12, further comprising:
forming an electrode contact portion to electrically connect the metal electrode, the light-receiving area, and the quench resistor through the insulating layer.

15. The method of claim 11, further comprising:
forming a substrate; and
forming an interlayer between the substrate and the insulating layer.

16. The method of claim 15, further comprising:
forming a junction doping layer on the interlayer; and
forming an upper doping layer on the junction doping layer.

17. The method of claim 15, wherein the substrate and the interlayer are formed using an epitaxy process.

18. The method of claim 16, wherein the upper doping layer and the junction doping layer are formed using an ion implantation process.

19. The method of claim 16, further comprising:
forming a guide ring between the interlayer and the insulating layer, and
wherein the guide ring prevents an occurrence of a premature breakdown at an edge of the upper doping layer.

20. The method of claim 16, wherein the substrate, the interlayer, the junction doping layer, and the upper doping layer are distinguished from one another based on a doping type and a concentration of silicon, and formed in a vertical diode structure.
